(19) United States
(12) Patent Application Publication
(10) Pub. No.: US 2010/0118500 A1
(43) Pub. Date: May 13, 2010

(54) HANDHELD ELECTRONIC DEVICE

(76) Inventors: Chung-Wei Wang, Taipei (TW); Chih-Hao Lu, Taipei (TW); Wen-Hung Wang, Taipei (TW)

Correspondence Address: Muncy, Geissler, Olds & Lowe, PLLC, P.O. BOX 1364, FAIRFAX, VA, 22038-1364, US

(21) Appl. No.: 12/617,547

(22) Filed: Nov. 12, 2009

(30) Foreign Application Priority Data
Nov. 13, 2008 (TW) 097143966

(51) Int. Cl. H05K 5/00

(52) U.S. Cl. 361/752; 361/679.01

(57) ABSTRACT

A handheld electronic device including an electronic device body and a ring is disclosed. The ring is connected with the electronic device body, and it has a plurality of extending portions extending toward the center of the ring.

### CROSS REFERENCE TO RELATED APPLICATIONS

This Non-provisional application claims priority under 35 U.S.C. §119(a) on Patent Application No(s). 097143966 filed in Taiwan, Republic of China on Nov. 13, 2008, the entire contents of which are hereby incorporated by reference.

### BACKGROUND OF THE INVENTION

1. Field of Invention

The invention relates to a handheld electronic device and, more particularly, to a handheld electronic device capable of being held easily.

2. Related Art

With the development of the science and the technology, many electronic devices have generally become necessary articles in modern people's daily life. More particularly, some handheld electronic devices, such as mobile phones, cameras, personal digital assistants (PDA) and so on, are small in size, and they are multifunctional and convenient to be used. Therefore, the handheld electronic devices can be taken by modern people with them. However, the pace of modern people's life is quick. When a handheld electronic device is used by a user, the handheld electronic device may fall from the hand of the user since the user may be in a hurry or hit other people or objects carelessly. Thus the handheld electronic device may be damaged. Furthermore, as the holding surface of the handheld electronic device is too smooth, the user may fail to grasp the handheld electronic device. Thus, the handheld electronic device easily slips out of the hand of the user.

At present, computer games have become more and more popular, and remote controllers for playing the computer games also become well known by people. A player usually holds a remote controller in his or her hands to play a computer game by controlling a role in the computer game. However, when playing the game, the player may move in a wide range, and he or she is also excited. Therefore, the remote controller in the hand of the player may easily fly off. Thus, the remote controller is easily damaged, and it may also injure the player or any other persons.

Some manufacturers provide silicone covers capable of protecting the remote controllers and neck straps capable of avoiding falling of the remote controllers. However, the silicone covers and the neck traps additionally manufactured may further increase manufacturing cost.

### SUMMARY OF THE INVENTION

One objective of the invention is to provide a handheld electronic device to improve the prior art.

The invention provides a handheld electronic device including an electronic device body and a ring. The ring is connected with the electronic device body, and it has a plurality of extending portions extending toward the center of the ring.

The handheld electronic device provided by the invention may not easily fall from the hand of a user during operation. Thus the handheld electronic device may not be damaged or injure other persons. When the user uses the handheld electronic device provided by the invention, he or she can freely control the handheld electronic device via the ring. Thus, the user can operate the handheld electronic device easily, conveniently, and comfortably.

These and other features, aspects, and advantages of the present invention will become better understood with regard to the following description, appended claims, and accompanying drawings.

### BRIEF DESCRIPTION OF THE DRAWINGS

FIG. 1 is a front view of a handheld electronic device according to a first preferred embodiment of the invention.

FIG. 2 is a side view of the handheld electronic device in FIG. 1.

FIG. 3A is an exploded diagram showing the handheld electronic device in FIG. 2 after a ring module is removed.

FIG. 3B is a partial enlarged view of a second casing in FIG. 3A.

FIG. 4A is a front view of a ring module in FIG. 2.

FIG. 4B is a sectional diagram of the ring module in FIG. 4A along a section line A-A′.

FIG. 4C is a top view of the ring module in FIG. 4A.

FIG. 5A is a front view of a ring module according to a second preferred embodiment of the invention.

FIG. 5B is a top view of the ring module in FIG. 5A.

FIG. 6A is a schematic diagram of a second casing according to the second preferred embodiment of the invention.

FIG. 6B is a partial enlarged view of the second casing in FIG. 6A.

FIG. 7 is a schematic diagram of a second casing of a handheld electronic device according to a third preferred embodiment of the invention.

### DETAILED DESCRIPTION OF THE INVENTION

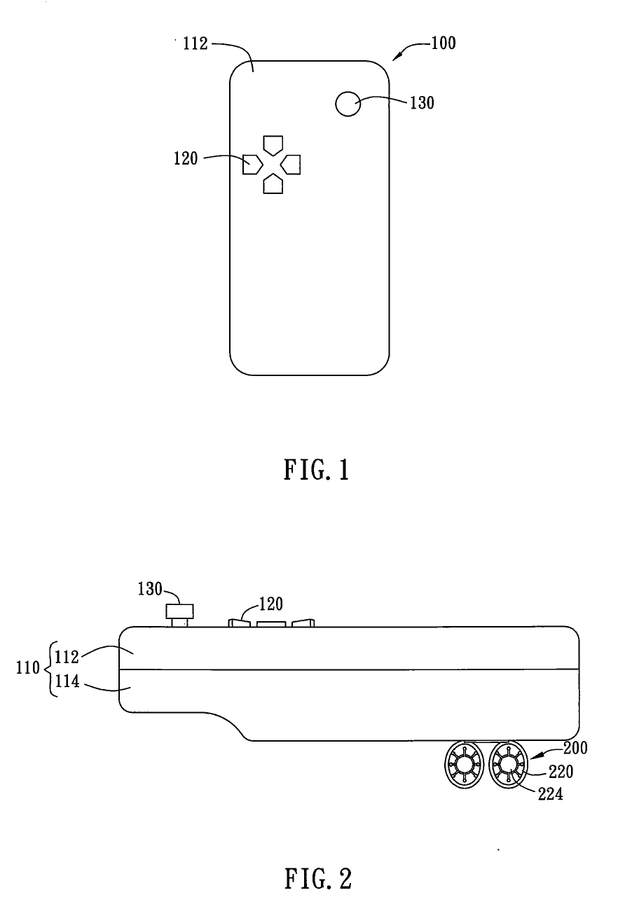

FIG. 1 is a front view of a handheld electronic device according to a first preferred embodiment of the invention. FIG. 2 is a side view of the handheld electronic device in FIG. 1. Please refer to FIG. 1 and FIG. 2. In the embodiment, a handheld electronic device 100 includes an electronic device body 110, a plurality of operating buttons 120, a joystick 130, and a ring module 200. The electronic device body 110 includes a first casing 112 and a second casing 114. The ring module 200 includes two rings 220, and each ring 220 has a first containing space 224. In other embodiments, the handheld electronic device 100 may have only one ring 220. The invention is not limited thereto.

In the embodiment, the handheld electronic device is a game remote controller. In other embodiments, the handheld electronic device may also be any other electronic devices such as a mobile phone, a personal digital assistant (PDA) and so on.

In FIG. 1 and FIG. 2, the operating buttons 120 and the joystick 130 are disposed at the first casing 112 of the handheld electronic device 100 for a user to operate. The first casing 112 and the second casing 114 are connected with each other to form the electronic device body 110. The ring module 200 is disposed at the second casing 114.

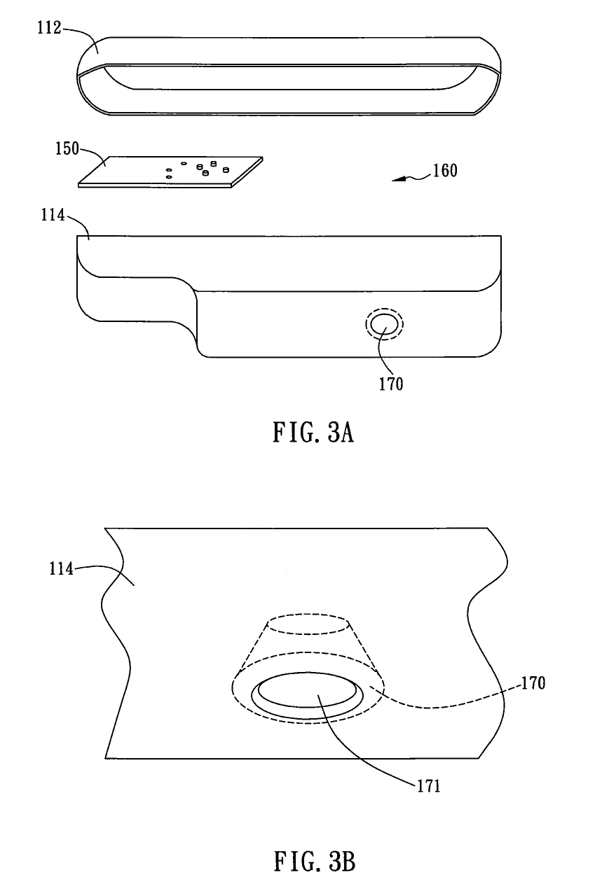

FIG. 3A is an exploded diagram showing the handheld electronic device in FIG. 2 after the ring module is removed. In FIG. 2 and FIG. 3A, the first casing 112 and the second casing 114 can form a second containing space 160. The handheld electronic device 100 further includes a circuit board 150 disposed in the second containing space 160. The circuit board 150 is electrically connected with the operating buttons 120 and the joystick 130, respectively, to receive operating signals transmitted by the operating buttons 120 and the joystick 130.

In the embodiment, the second casing 114 further has a recessed hole 170 at the bottom for connecting the ring module 200. In other embodiments, the ring module 200 may be connected with the second casing 114 in other modes. The invention is not limited thereto.

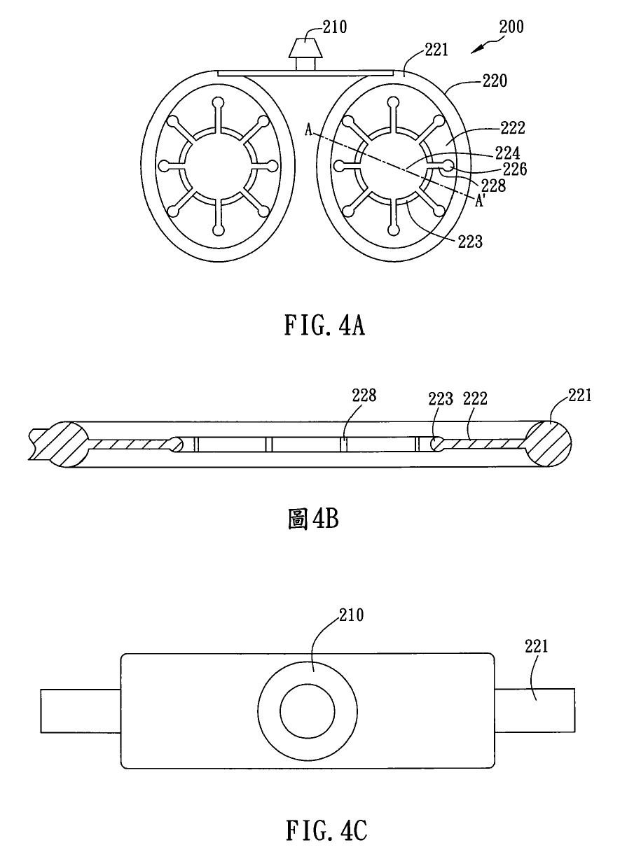

FIG. 3B is a partial enlarged view of the second casing in FIG. 3A. In FIG. 3B, the second casing 114 has a recessed hole 170 and an opening 171, the recessed hole 170 of the second casing 114 is cone-shaped. The area of the opening 171 is less than the base area of the recessed hole 170. Thus, the connecting element 210 (as shown in FIG. 4A) is fastened to the recessed hole 170. In other embodiments, the recessed hole 170 may have any other shapes. The invention is not limited thereto.

FIG. 4A is a front view of the ring module in FIG. 2. FIG. 4B is a sectional diagram of the ring module in FIG. 4A along a section line A-A′. FIG. 4C is a top view of the ring module in FIG. 4A. In FIGS. 4A-4C, according to the embodiment, the ring module 200 has a cone-shaped connecting element 210 corresponding to the recessed hole.

In FIG. 4A and FIG. 3B, the connecting element 210 can be fastened to the recessed hole 170 of the second casing 114 through the opening 171. The ring module 200 may be made of plastic, and it is elastic. Thereby, the extending portions 222 are elastic. In other embodiments, the connecting element 210 may have any other shapes. The invention is not limited thereto.

In the embodiment, since the connecting element 210 is cone-shaped and disposed in the recessed hole 170, the recessed hole 170 can be designed to be a litter larger than the connecting element 210. Thus, the connecting element 210 can rotate in the recessed hole 170. When a user exerts a force on the ring 220, the connecting element 210 can rotate to avoid being damaged. The user can also adjust the position of the ring module 200 according to his or her custom. In other embodiments, the connecting element 210 and the recessed hole 170 may also be designed to be transitionally fitted or to be tightly fitted as needed. The invention is not limited thereto.

In the embodiment, the ring module 200 has two ring-shaped rings 220 as shown in FIG. 4A. In other embodiments, the ring module 200 may have only one ring 220 or more than two rings 220. The invention is not limited thereto. Each ring 220 may be integrally formed. The ring 220 may be circular, oval-shaped, or petal-shaped, or it may have any other shapes. The invention is not limited thereto.

Each ring 220 has an outer rim portion 221, a plurality of extending portions 222, a plurality of inner rim portions 223, a first containing space 224, and a plurality of gaps 228. The outer rim portion 221 is located at the peripheral portion of the ring 220. The extending portions 222 extend from the outer rim portion 221 to the inner rim portions 223. The inner rim portions 223 correspond to the extending portions 222, respectively. In FIG. 4B, a thickness of the outer rim portion 221 is greater than that of the inner rim portions 223, and the thickness of the inner rim portions 223 is greater than that of the extending portions 222, thus to enhance holding comfort for the user.

The extending portions 222 extend toward the center of the ring 220 to form the first containing space 224. When the user operates the handheld electronic device 100, he or she can insert his or her finger into the first containing space 224. Thus, the user need not worry that the handheld electronic device may fall from or fly off from the hand. In FIG. 4B, sections of the inner rim portions 223 and the outer rim portion 221 may be circular, thus to provide better holding comfort.

In FIG. 4A, each gap 228 is located between two extending portions, and one end of each gap 228 is connected to the first containing space 224. Preferably, the gaps 228 are radially distributed in the ring 220. Thereby, because of the gaps 228, the ring 220 may not be easily damaged by an external force. For example, when the user holds the handheld electronic device 100 via the ring module 200, and the user exerts a force on the rings 220, the gaps 228 can prevent the force from damaging the rings 220. For example, the gaps 228 can prevent the rings from splitting.

Preferably, the ring 220 can further have a plurality of openings 226. The other end of the gap 228 is connected to the opening 226, and the gaps 228 correspond to the openings 226, respectively. The openings 226 can provide better protection to prevent the ring 220 from being damaged caused by the external force.

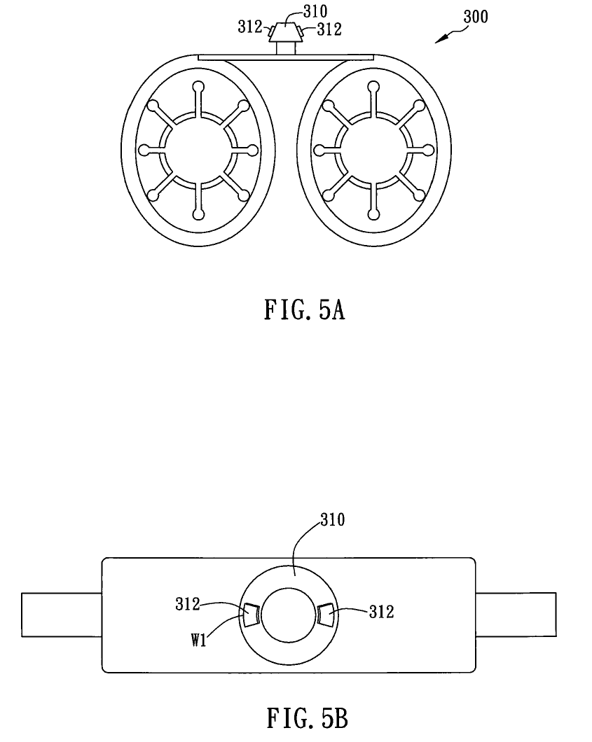

FIG. 5A is a front view of a ring module according to a second preferred embodiment of the invention. FIG. 5B is a top view of the ring module in FIG. 5A. In FIG. 5A, a ring module 300 is similar to the ring module 200 in the first preferred embodiment. Therefore, it is not described for a concise purpose. The difference is that a connecting element 310 of the ring module 300 has two protrudent portions 312.

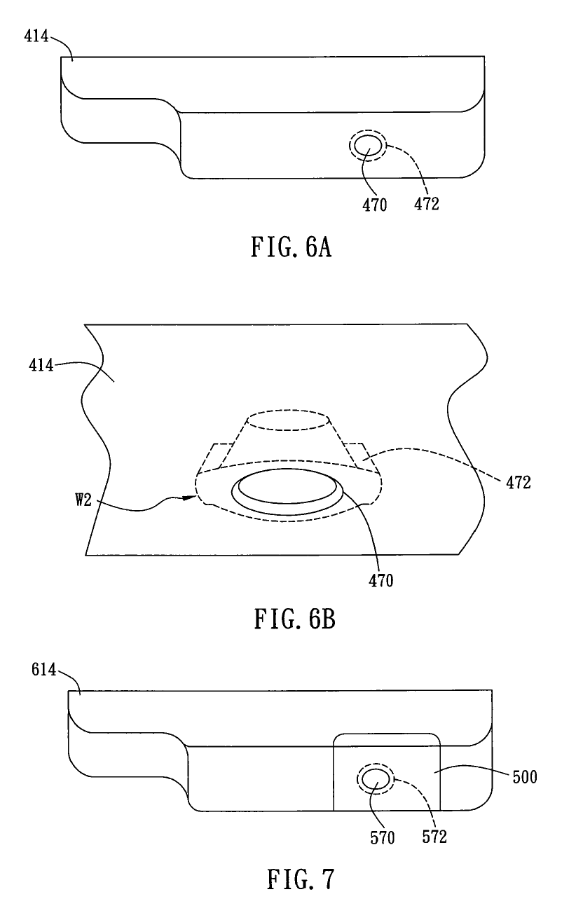

FIG. 6A is a schematic diagram of a second casing according to the second preferred embodiment of the invention. FIG. 6B is a partial enlarged view of the second casing in FIG. 6A. A second casing 414 is similar to the second casing 114 in the first preferred embodiment. Therefore, it is not described for a concise purpose. The difference is that a recessed hole 470 of the second casing 414 has two recessed portions 472 to contain the protrudent portions 312.

In FIG. 5B and FIG. 6B, preferably, the width W2 of the bottom of the recessed portions 472 can be greater than the width W1 of the bottom of the protrudent portions 312. Thereby, the protrudent portions 312 are fastened to the recessed portions 472 in a certain range. Thus, the ring module 300 can rotate in a certain range.

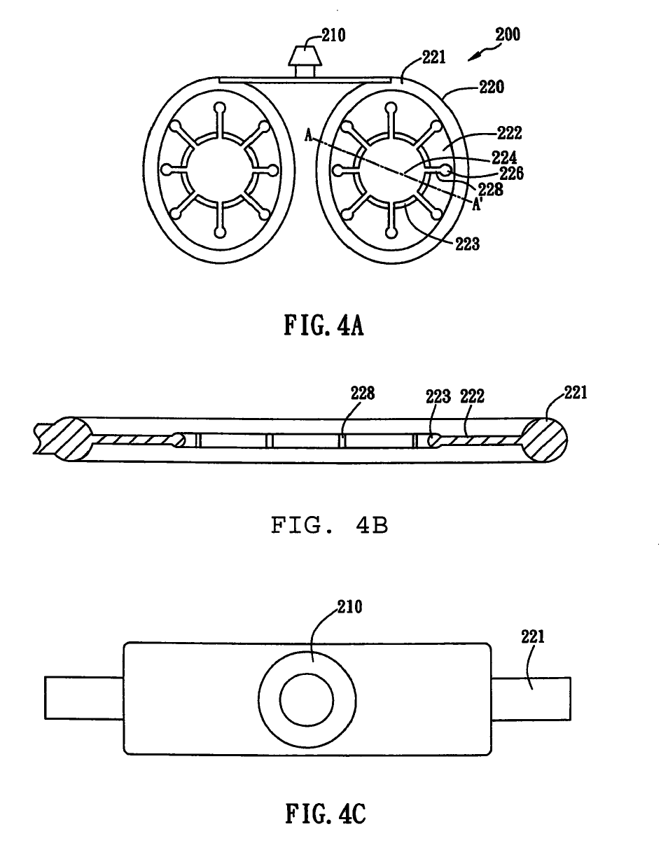

FIG. 7 is a schematic diagram of a second casing of a handheld electronic device according to a third preferred embodiment of the invention. Preferably, the handheld electronic device further includes a holding element 500 disposed at a second casing 614. Preferably, the holding element 500 and the second casing 614 are integrally formed via a co-injection molding process. A recessed hole 570 is disposed at the holding element 500. In the same way, the recessed hole 570 can have a recessed portion 572 for connecting the ring module.

According to the preferred embodiment of the invention, when the handheld electronic device is held by the user, it may not easily fall from or fly off from the hand of the user. Thus the handheld electronic device may not be damaged or injure other persons. Furthermore, when the user uses the handheld electronic device provided by the preferred embodiment of the invention, he or she can freely and comfortably operate the handheld electronic device via the ring module.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A handheld electronic device comprising:
an electronic device body; and
a ring connected with the electronic device body and having a plurality of extending portions extending toward the center of the ring.

2. The handheld electronic device according to claim 1, wherein the extending portions are elastic.

3. The handheld electronic device according to claim 1, wherein the extending portions have gaps between each other.

4. The handheld electronic device according to claim 3, wherein the gaps are distributed radially.

5. The handheld electronic device according to claim 1, wherein the ring further has an outer rim portion located at the peripheral portion of the ring and a plurality of inner rim portions, the extending portions extend from the outer rim portion to the inner rim portions, and the inner rim portions correspond to the extending portions, respectively.

6. The handheld electronic device according to claim 5, wherein a thickness of the outer rim portion is greater than that of the inner rim portions, and the thickness of the inner rim portions is greater than that of the extending portions.

7. The handheld electronic device according to claim 5, wherein sections of the outer rim portion and the inner rim portions are circular or oval-shaped.

8. The handheld electronic device according to claim 1, wherein the ring is made of plastic.

9. The handheld electronic device according to claim 1, further comprising a connecting element for connecting the ring and the electronic device body.

10. The handheld electronic device according to claim 9, wherein the electronic device body has a recessed hole, and the connecting element is disposed in the recessed hole.

11. The handheld electronic device according to claim 1, further comprising at least one operating button and a circuit board disposed in the electronic device body, and the operating button is electrically connected with the circuit board.

12. The handheld electronic device according to claim 11, wherein the electronic device body includes a first casing and a second casing, the operating button is disposed at the first casing, and the ring is connected with the second casing.

13. The handheld electronic device according to claim 11, wherein the electronic device body includes a first casing, a second casing, and a holding element, the operating button is disposed at the first casing, the holding element and the second casing are integrally formed via a co-injection molding process, and the ring is connected with the holding element.
